(19) United States
(12) Patent Application Publication
(10) Pub. No.: US 2025/0372585 A1
(43) Pub. Date: Dec. 4, 2025

(54) INTEGRATED SYSTEM IN PACKAGE

(71) Applicant: Advanced Micro Devices, Inc., Santa Clara, CA (US)

(72) Inventor: Mahadevan Suryakumar, Austin, TX (US)

(73) Assignee: Advanced Micro Devices, Inc., Santa Clara, CA (US)

(21) Appl. No.: 18/332,540

(22) Filed: Jun. 9, 2023

(51) Int. Cl. H01L 25/16; H01L 23/31; H01L 23/367; H01L 23/498; H05K 1/18; H05K 3/00; H05K 3/30

(52) U.S. Cl. CPC H01L 25/162; H01L 23/367; H05K 1/181; H05K 3/30; H01L 23/3121; H01L 23/49833; H05K 3/0047; H05K 2201/09072; H05K 2201/10015; H05K 2201/1003; H05K 2201/10159; H05K 2201/10515; H05K 2201/10522

(57) ABSTRACT

The disclosed device package includes a processing unit having a first thermal regulation surface and a power delivery unit having a second thermal regulation surface. The power delivery unit is mounted on the processing unit such that the second thermal regulation surface is opposite the first thermal regulation surface. Various other methods, systems, and computer-readable media are also disclosed.

### BACKGROUND

Certain computing devices, such as mobile devices, wearable devices, etc., require a small printed circuit board (PCB) due to size constraints. Some components, particularly memory components and power delivery components, have footprints that often contribute to the overall PCB size. Although efficient rearrangement of components can reduce the PCB size, mechanical and thermal limitations, as well as fabrication and assembly considerations can often restrict such component rearrangement.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a block diagram of an exemplary system for an integrated system-in-package (SIP).

FIGS. 2A-D are diagrams of various exemplary integrated system-in-packages (SIP).

FIG. 3 is a flow diagram of an exemplary method for producing an integrated SIP.

Throughout the drawings, identical reference characters and descriptions indicate similar, but not necessarily identical, elements. While the exemplary implementations described herein are susceptible to various modifications and alternative forms, specific implementations have been shown by way of example in the drawings and will be described in detail herein. However, the exemplary implementations described herein are not intended to be limited to the particular forms disclosed. Rather, the present disclosure covers all modifications, equivalents, and alternatives falling within the scope of the appended claims.

### DETAILED DESCRIPTION

The present disclosure is generally directed to an integrated system-in-package (SIP). As will be explained in greater detail below, implementations of the present disclosure provide a device package including a first and second component. The second component is mounted on the first component such that a first thermal regulation surface of the first component is opposite a second thermal regulation surface of the second component, allowing both components to be thermally managed. Additional components can be mounted between the first and second components to provide an advanced SIP advantageously having a small footprint.

In one implementation, a device package for an integrated SIP includes a first component having a first thermal regulation surface, and a second component having a second thermal regulation surface. The second component can be mounted on the first component such that the second thermal regulation surface is opposite the first thermal regulation surface.

In some examples, the device package further includes a third component mounted between the first component and the second component. In some examples, the third component includes a package mold having a through mold via (TMV) coupling the first component to the second component. In some examples, the device package includes a passive component for the first component or the second component that includes the TMV. In some examples, the passive component comprises the TMV encapsulated in a magnetic medium or a high dielectric medium.

In some examples, the third component corresponds to a memory. In some examples, the device package further includes a thermal management device mounted on the first thermal regulation surface. In some examples, the first component corresponds to a processing unit. In some examples, the second component corresponds to a power delivery circuit.

In one implementation, a system for an integrated SIP includes a printed circuit board (PCB) having a hole, and a device package mounted on the PCB. The device package includes a first component having a first thermal regulation surface, and a second component having a second thermal regulation surface. The second component can be mounted on the first component such that the second thermal regulation surface is opposite the first thermal regulation surface, and the first thermal regulation surface is exposed through the hole.

In some examples, the device package further includes a third component mounted between the first component and the second component. In some examples, the third component comprises a package mold having a through mold via (TMV) coupling the first component to the second component. In some examples, the system further includes a passive component for the first component or the second component that includes the TMV. In some examples, the passive component comprises the TMV encapsulated in a magnetic medium or a high dielectric medium.

In some examples, the third component corresponds to a memory. In some examples, the system further includes a thermal management device mounted on the first thermal regulation surface through the hole. In some examples, the first component corresponds to a processing unit. In some examples, the second component corresponds to a power delivery circuit.

In one implementation, a method for producing an integrated SIP includes (i) forming a hole through a printed circuit board (PCB), (ii) mounting, onto the PCB, a device package having a first component having a first thermal regulation surface and a second component having a second thermal regulation surface such that the first thermal regulation surface is exposed through the hole, wherein the second component is mounted on the first component such that the second thermal regulation surface is opposite the first thermal regulation surface, and (iii) attaching a first thermal management device onto the first thermal regulation surface through the hole.

In some examples, the method further includes attaching a second thermal management device onto the second thermal regulation surface.

Features from any of the implementations described herein can be used in combination with one another in accordance with the general principles described herein. These and other implementations, features, and advantages will be more fully understood upon reading the following detailed description in conjunction with the accompanying drawings and claims.

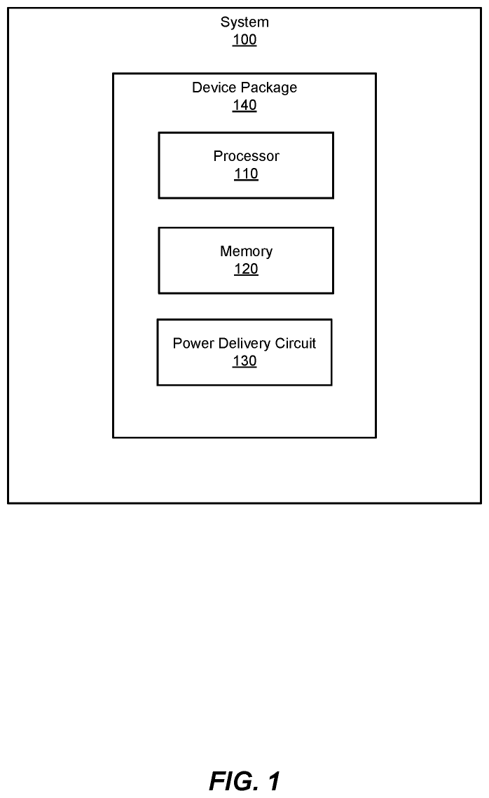

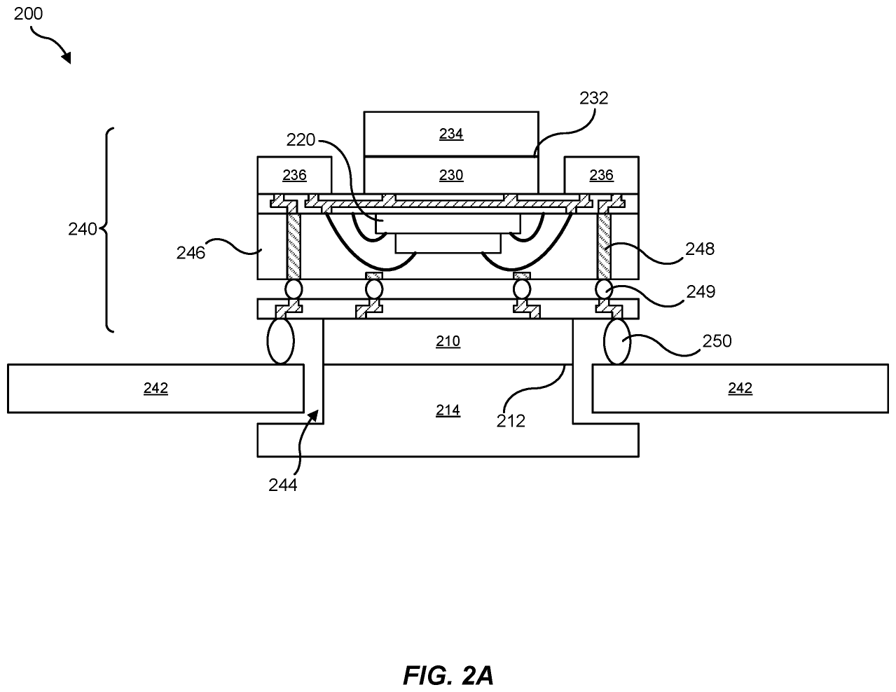

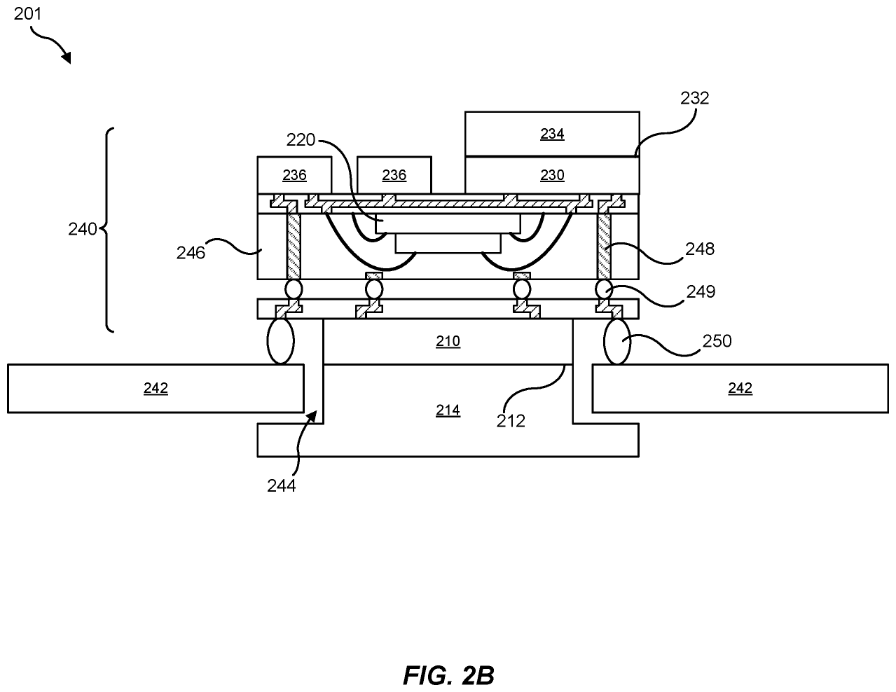

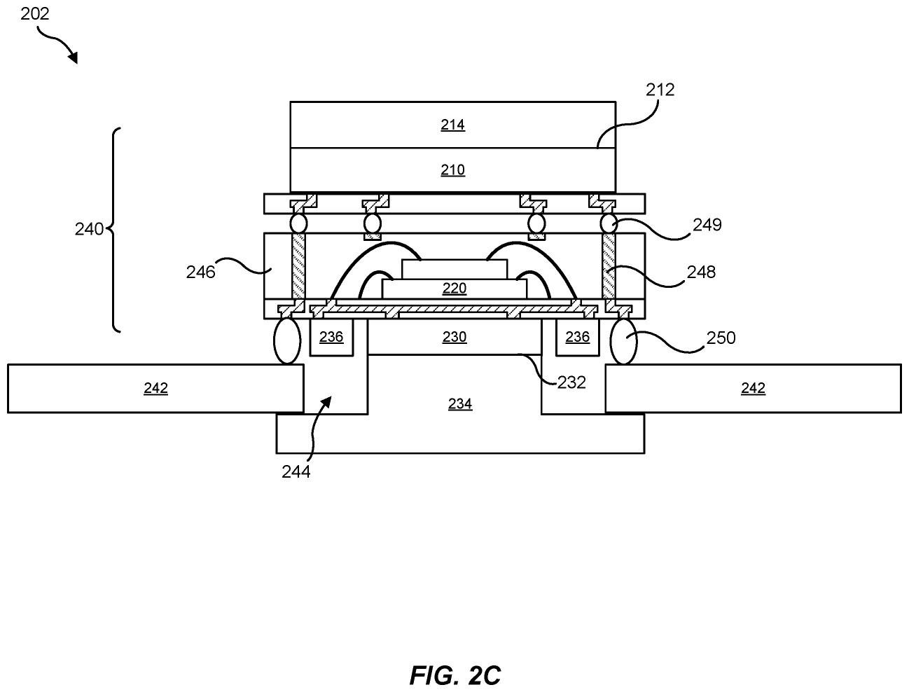

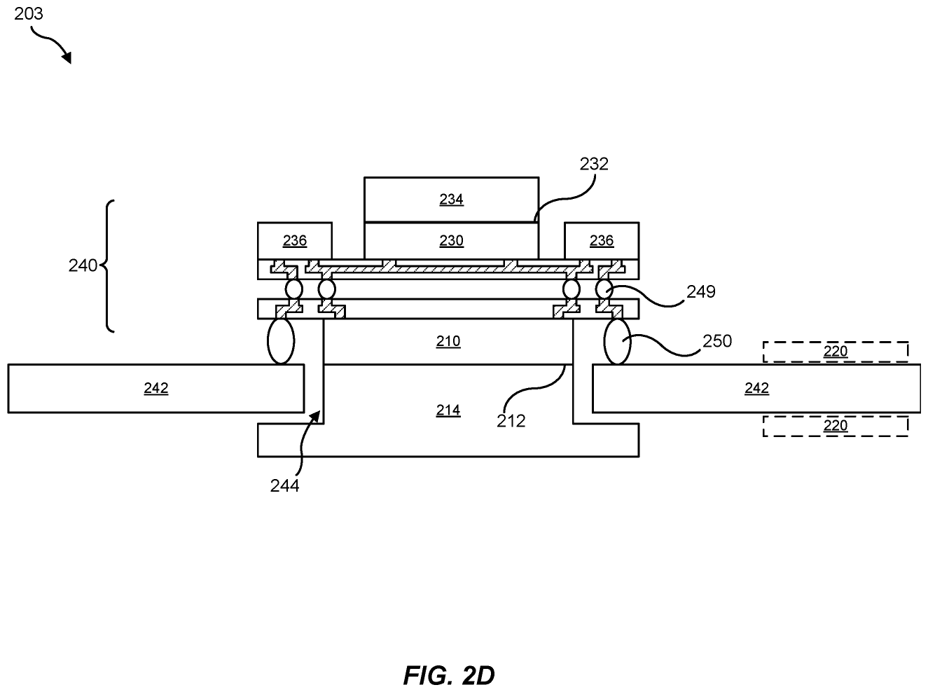

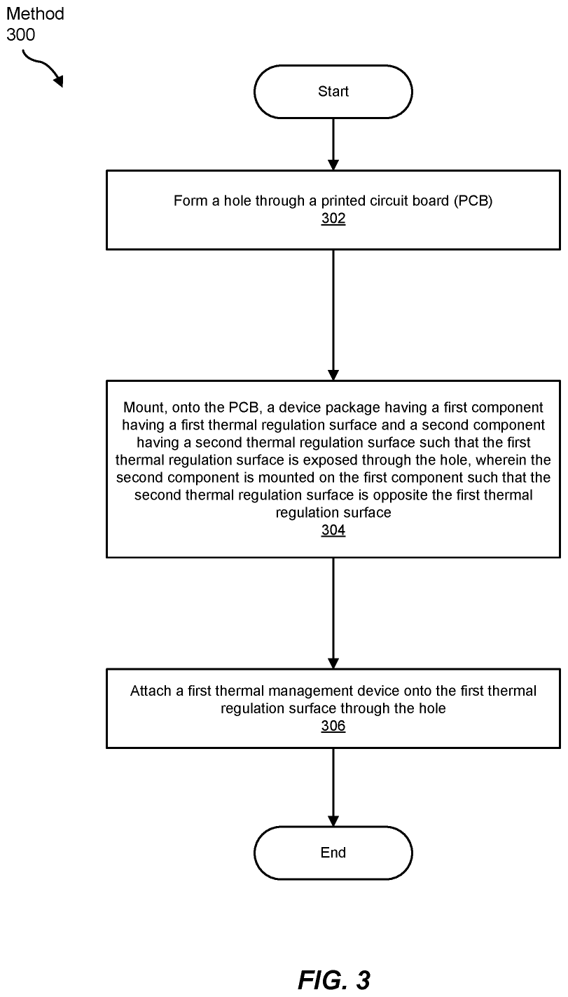

The following will provide, with reference to FIGS. 1-3, detailed descriptions of an integrated SIP. Detailed descriptions of example systems and packages for an integrated SIP will be provided in connection with FIGS. 1 and 2. Detailed descriptions of corresponding computer-implemented methods will also be provided in connection with FIG. 3.

FIG. 1 is a block diagram of an example system 100 for an integrated SIP. System 100 corresponds to a computing device, such as a desktop computer, a laptop computer, a server, a tablet device, a mobile device, a smartphone, a wearable device, an augmented reality device, a virtual reality device, a network device, and/or an electronic device. As illustrated in FIG. 1, system 100 includes one or more memory devices, such as memory 120. Memory 120 generally represents any type or form of volatile or non-volatile storage device or medium capable of storing data and/or computer-readable instructions. Examples of memory 120 include, without limitation, Random Access Memory (RAM), Read Only Memory (ROM), flash memory, Hard Disk Drives (HDDs), Solid-State Drives (SSDs), optical disk drives, caches, variations, or combinations of one or more of the same, and/or any other suitable storage memory.

As illustrated in FIG. 1, example system 100 includes one or more physical processors, such as processor 110. Processor 110 generally represents any type or form of hardware-implemented processing unit capable of interpreting and/or executing computer-readable instructions. In some examples, processor 110 accesses and/or modifies data and/or instructions stored in memory 120. Examples of processor 110 include, without limitation, chiplets (e.g., smaller and in some examples more specialized processing units that can coordinate as a single chip), microprocessors, microcontrollers, Central Processing Units (CPUs), graphics processing units (GPUs), Field-Programmable Gate Arrays (FPGAs) that implement softcore processors, Application-Specific Integrated Circuits (ASICs), systems on chip (SoCs), digital signal processors (DSPs), Neural Network Engines (NNEs), accelerators, graphics processing units (GPUs), portions of one or more of the same, variations or combinations of one or more of the same, and/or any other suitable physical processor.

FIG. 1 also illustrates a power delivery circuit 130. Power delivery circuit 130 corresponds to circuitry for a power delivery network, such as a voltage regulator and other circuits for providing power to components of system 100 including processor 110 and memory 120.

As further illustrated in FIG. 1, system 100 includes a device package 140. Device package 140 corresponds to an SIP and includes at least processor 110, memory 120, and power delivery circuit 130. As will be described further below, device package 140 can be arranged to minimize a footprint (e.g., on a PCB) of processor 110, memory 120, and/or power delivery circuit 130.

FIG. 2A illustrates a system 200 corresponding to system 100. FIG. 2A illustrates a simplified cross-sectional view of a device package 240, corresponding to device package 140, mounted on a PCB 242. Device package 240 includes a first component 210 having a first thermal regulation surface 212 and a second component 230 having a second thermal regulation surface 232. As illustrated in FIG. 2A, second component 230 is mounted on first component 210 such that second thermal regulation surface 232 is opposite (e.g., facing away from) first thermal regulation surface 212.

In some examples, first component 210 corresponds to a circuit using thermal management for normal operation, such as processor 110, an SoC, etc. First component 210 can use a first thermal management device 214, corresponding to a notched heat spreader or any passive and/or active thermal management device, attached to first thermal regulation surface 212 for thermal management. In other examples, first thermal management device 214 can have different shapes and/or interface with different components.

In some examples, second component 230 corresponds to a circuit using thermal management for normal operations, such as power delivery circuit 130. Second component 230 can use a second thermal management device 234, corresponding to a heat sink or any passive and/or active thermal management device, attached to second thermal regulation surface 232 for thermal regulation. In some examples, second component 230 can include, incorporate, or be connected to one or more discrete components 236, which can correspond to passive components such as capacitors, inductors, etc. In other examples, second thermal management device 234 can have different shapes and/or interface with different components (e.g., discrete components 236).

As illustrated in FIG. 2A, first component 210 and second component 230 are mounted together such that first thermal regulation surface 212 and second thermal regulation surface 232 face away from each other, allowing application of first thermal regulation device 214 and second thermal management device 234. As further illustrated in FIG. 2A, PCB 242 includes a hole 244. Device package 240, and more specifically first component 210, is mounted onto PCB 242 such that first thermal regulation surface 212 is exposed through hole 244, providing space to apply first thermal regulation device 214.

In some implementations, device package 240 further includes a third component 220 mounted between first component 210 and second component 230. Third component 220 corresponds to a circuit that can operate normally without requiring a thermal regulation device, such as memory 120. In some implementations, additional components that can operate normally without a thermal regulation device can further be mounted between first component 210 and second component 230. Accordingly, device package 240 can combine various integrated circuits (e.g., first component 210, second component 230, and third component 220) in a way that further allows thermal regulation devices (e.g., first thermal regulation device 214 and second thermal management device 234) to be attached as needed.

One or more components in device package 240 can include or be encapsulated in a package mold or other package. In FIG. 2A, third component 220 can be encapsulated in a mold 246 (e.g., as a memory package). A through-mold via (TMV) 248 and a mid-level interconnect 249 can provide a connection between first component 210 and second component 230 extending through a space holding third component 220 (e.g., through mold 246). In addition, device package 240 (and components therein) can be connected to PCB 242 via an annular ball grid arrangement 250 around hole 244, as illustrated in FIG. 2. Vertically delivering power (e.g., using TMV 248) from second component 230 to first component 210 can be more efficient (e.g., suffers less loss/noise) than horizontally delivering power along PCB 242 through interconnects to improve power efficiency and performance. As also shown in FIG. 2A, various interconnects, bumps, wires, etc. connect the different components.

For further efficiency in using space, in some examples TMV 248 can form or be integrated into a passive component, such as a passive component for first component 210, second component 230, and/or third component 220. For example, TMV 248 can be encapsulated in a magnetic medium and/or a high dielectric medium to form a passive component such as an inductor or capacitor, that can be incorporated with second component 230 (e.g., as an inductor or capacitor for a voltage regulator). In some examples, including TMV 248 in a passive component can further reduce a footprint of second component 230 (e.g., by removing discrete components 236).

One or more components in device package 240 can correspond to a stacked die. For example, in FIG. 2A, third component 220 is a stacked die having two tiers, although in other examples, third component 220 can include additional tiers. In yet other examples, first component 210 and/or second component 230 can include a stacked die structure of two or more tiers.

FIG. 2B illustrates a system 201 corresponding to an alternative example of system 200 in FIG. 2A. As illustrated in FIG. 2B, the various components can be positioned in alternative arrangements as needed. For instance, in FIG. 2B, second component 230 can be offset from first component 210, including shifting positions of discrete components 236, while retaining the various connections between components (e.g., first component 210 being connected to second component 230 through mid-level interconnect 249, TMV 248 and various interconnects, traces, wires, etc. therebetween).

FIG. 2C illustrates a system 202 corresponding to another alternative example of system 200 in FIG. 2A. As illustrated in FIG. 2C, second component 230 can be mounted on PCB 242 such that second thermal regulation surface 232 is exposed through hole 244, providing space to apply second thermal regulation device 234. First component 210 is mounted away from PCB 242 but is coupled to PCB 242 via annular ball grid arrangement 250, TMV 248, mid-level interconnect 249, and various interconnects, traces, wires, etc. therebetween. In addition, although not specifically shown in the simplified cross-sectional view of FIG. 2C, first component 210 can be connected to second component 230 through various vias, interconnects, traces, wires, etc.

FIG. 2D illustrates a system 203 of yet another alternative example of system 200 in FIG. 2A. In FIG. 2D, second component 230 can be more directly mounted onto first component 210 (e.g., without third component 220 and mold 246). In FIG. 2D, third component 220 can be mounted elsewhere for example laterally from device package 240 on a same side of PCB 242 as device package 240 or on an opposite side of PCB 242 as device package 240) as optionally illustrated in FIG. 2D. In some examples, third component 220 can be unneeded (e.g., such that first component 210 and/or second component 230 would not be connected to third component 220).

FIG. 3 is a flow diagram of an exemplary method 300 for assembling an integrated SIP. The steps shown in FIG. 3 can be performed by any suitable device manufacturing/fabricating system. In one example, each of the steps shown in FIG. 3 represent an algorithm whose structure includes and/or is represented by multiple sub-steps, examples of which will be provided in greater detail below.

As illustrated in FIG. 3, at step 302 one or more of the systems described herein form a hole through a printed circuit board (PCB). For example, hole 244 can be formed in PCB 242.

The systems described herein can perform step 302 in a variety of ways. In one example, PCB 242 can be formed, and hole 244 drilled (e.g., by a router) or otherwise opened in PCB 242. In another example, PCB 242 can be formed having hole 244. Hole 244 can be dimensioned to accept first component 210 (e.g., an SoC) and/or second component 230 (e.g., a power delivery circuit).

At step 304 one or more of the systems described herein mount, onto the PCB, a device package. The device package (e.g., device package 240) can have a first component (e.g., first component 210 in FIGS. 2A, 2B, and 2D, or alternatively second component 230 in FIG. 2C) having a first thermal regulation surface (e.g., first thermal regulation surface 212 in FIGS. 2A, 2B, and 2D, or alternatively second thermal regulation surface 232 in FIG. 2C) and a second component (e.g., second component 230 in FIGS. 2A, 2B, and 2D, or alternatively first component 210 in FIG. 2C) having a second thermal regulation surface (e.g., second thermal regulation surface 232 in FIGS. 2A, 2B, and 2D, or alternatively first thermal regulation surface 212 in FIG. 2C) such that the first thermal regulation surface is exposed through the hole. In addition, the second component is mounted on the first component such that the second thermal regulation surface is opposite the first thermal regulation surface (see, e.g., FIGS. 2A-2D).

The systems described herein can perform step 304 in a variety of ways. In one example, the device package can be manufactured first and then mounted onto PCB 242. In another example, the device package can be manufactured through piecewise mounting onto PCB 242.

In some examples, the device package can further include a third component (e.g., third component 220) mounted between the first component and the second component. The third component can include a package mold having a TMV coupling the first component to the second component (see, e.g., FIGS. 2A-2C).

At step 306 one or more of the systems described herein attach a first thermal management device onto the first thermal regulation surface through the hole. For example, with the first thermal regulation surface being exposed through the hole, the first thermal management device (e.g., first thermal management device 214 in FIGS. 2A, 2B, and 2D or alternatively second thermal management device 234 in FIG. 2C) can be appropriately mounted onto the first thermal regulation surface (e.g., using thermal grease, etc.) through the hole.

The systems described herein can perform step 306 in a variety of ways. In one example, a second thermal management device (e.g., second thermal management device 234 in FIGS. 2A, 2B, and 2C or alternatively first thermal management device 214 in FIG. 2C) can be attached onto the second thermal regulation surface, although in other examples the second thermal management device can be attached when manufacturing the device package.

As detailed above, the present disclosure relates to an advanced system-in-package (SIP) that can use hybrid silicon wafer integrated fanout technology (SWIFT) with a re-distribution layer (RDL) package-on-package (POP) that can integrate a system-on-chip (SoC) or processing unit, a power delivery circuit, memory (e.g., dynamic random access memory (DRAM)) to allow printed circuit board (PCB) X-Y reduction for handheld/mobile devices.

Handheld/mobile devices often require a smaller PCB due to size restrictions. The footprint from memory components and power delivery components in the PCB can be a significant contributor to the overall PCB X-Y size. Planar and vertical integration techniques have limitations/restrictions. Thus, the systems and methods described herein integrate memory, power delivery, and processing (e.g., SoC) components in a vertical integration, such as by using SWIFT with RDL and POP. For example, the SoC die can be placed on a ball grid array (BGA) side of the SWIFT package. A hole in the PCB allows for a thermal cooling solution, such as a notched head spreader, for the SoC. A memory (DRAM) package can mate with the SoC package on the opposite side of the SoC die.

The DRAM package can include through-mold vias (TMV) to provide power delivery connections to/from the power delivery components placed on top of the DRAM package. The TMVs can further be encapsulated in a magnetic medium or high dielectric medium to form passive components for integrated voltage regulation to further reduce the power delivery footprint. In addition, the close proximity of the power delivery circuit to the SoC and DRAM can improve power delivery performance.

As detailed above, the circuits, devices, and systems described and/or illustrated herein broadly represent any type or form of computing device or system capable of executing computer-readable instructions. In their most basic configuration, these computing device(s) each include at least one memory device and at least one physical processor.

In some examples, the term “memory device” generally refers to any type or form of volatile or non-volatile storage device or medium capable of storing data and/or computer-readable instructions. In one example, a memory device stores, loads, and/or maintains one or more of the modules and/or circuits described herein. Examples of memory devices include, without limitation, Random Access Memory (RAM), Read Only Memory (ROM), flash memory, Hard Disk Drives (HDDs), Solid-State Drives (SSDs), optical disk drives, caches, variations, or combinations of one or more of the same, or any other suitable storage memory.

In some examples, the term “physical processor” generally refers to any type or form of hardware-implemented processing unit capable of interpreting and/or executing computer-readable instructions. In one example, a physical processor accesses and/or modifies one or more modules stored in the above-described memory device. Examples of physical processors include, without limitation, microprocessors, microcontrollers, Central Processing Units (CPUs), Field-Programmable Gate Arrays (FPGAs) that implement softcore processors, Application-Specific Integrated Circuits (ASICs), systems on a chip (SoCs), digital signal processors (DSPs), Neural Network Engines (NNEs), accelerators, graphics processing units (GPUs), portions of one or more of the same, variations or combinations of one or more of the same, or any other suitable physical processor.

In some implementations, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein are shown or discussed in a particular order, these steps do not necessarily need to be performed in the order illustrated or discussed. The various exemplary methods described and/or illustrated herein can also omit one or more of the steps described or illustrated herein or include additional steps in addition to those disclosed.

The preceding description has been provided to enable others skilled in the art to best utilize various aspects of the exemplary implementations disclosed herein. This exemplary description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A device package comprising:
a first component having a first thermal regulation surface; and
a second component having a second thermal regulation surface;
wherein the second component is mounted on the first component such that the second thermal regulation surface is opposite the first thermal regulation surface.

2. The device package of claim 1, further comprising a third component mounted between the first component and the second component.

3. The device package of claim 2, wherein the third component comprises a package mold having a through mold via (TMV) coupling the first component to the second component.

4. The device package of claim 3, further comprising a passive component for the first component or the second component that includes the TMV.

5. The device package of claim 4, wherein the passive component comprises the TMV encapsulated in a magnetic medium or a high dielectric medium.

6. The device package of claim 2, wherein the third component corresponds to a memory.

7. The device package of claim 1, further comprising a thermal management device mounted on the first thermal regulation surface.

8. The device package of claim 1, wherein the first component corresponds to a processing unit.

9. The device package of claim 1, wherein the second component corresponds to a power delivery circuit.

10. A system comprising:
a printed circuit board (PCB) having a hole; and
a device package mounted on the PCB and comprising:
a first component having a first thermal regulation surface; and
a second component having a second thermal regulation surface;
wherein the second component is mounted on the first component such that the second thermal regulation surface is opposite the first thermal regulation surface, and the first thermal regulation surface is exposed through the hole.

11. The system of claim 10, wherein the device package further comprises a third component mounted between the first component and the second component.

12. The system of claim 11, wherein the third component comprises a package mold having a through mold via (TMV) coupling the first component to the second component.

13. The system of claim 12, further comprising a passive component for the first component or the second component that includes the TMV.

14. The system of claim 13, wherein the passive component comprises the TMV encapsulated in a magnetic medium or a high dielectric medium.

15. The system of claim 11, wherein the third component corresponds to a memory.

16. The system of claim 10, further comprising a thermal management device mounted on the first thermal regulation surface through the hole.

17. The system of claim 10, wherein the first component corresponds to a processing unit.

18. The system of claim 10, wherein the second component corresponds to a power delivery circuit.

19. A method comprising:
forming a hole through a printed circuit board (PCB);
mounting, onto the PCB, a device package having a first component having a first thermal regulation surface and a second component having a second thermal regulation surface such that the first thermal regulation surface is exposed through the hole; wherein the second component is mounted on the first component such that the second thermal regulation surface is opposite the first thermal regulation surface; and
attaching a first thermal management device onto the first thermal regulation surface through the hole.

20. The method of claim 19, further comprising:
attaching a second thermal management device onto the second thermal regulation surface.
